(19) United States
(12) Patent Application Publication
(10) Pub. No.: US 2015/0136732 A1
(43) Pub. Date: May 21, 2015

(54) METHOD AND APPARATUS FOR FILM DEPOSITION

(71) Applicant: Applied Materials, Inc., Santa Clara, CA (US)

(72) Inventors: Xianmin TANG, San Jose, CA (US); Ludovic GODET, Sunnyvale, CA (US); Guojun LIU, San Jose, CA (US); Jing TANG, San Jose, CA (US); Phillip STOUT, Santa Clara, CA (US); Rong TAO, San Jose, CA (US)

(21) Appl. No.: 14/547,702

(22) Filed: Nov. 19, 2014

Related U.S. Application Data
(60) Provisional application No. 61/907,109, filed on Nov. 21, 2013.

(51) Int. Cl. C23C 16/56; C23C 14/50; C23C 16/458; C23C 14/00

(52) U.S. Cl. CPC C23C 16/56; C23C 14/0005; C23C 14/505; C23C 16/4584
USPC 216/37; 156/345.1; 156/345.55

(57) ABSTRACT

A method and apparatus for depositing films on a substrate is described. The method includes depositing a film on a substrate with feature formed therein or thereon. The feature includes a first surface and a second surface that are at different levels. A least a portion of the deposited film is removed by exposing the substrate to an ion flux from a linear ion source. The ion flux has an ion angular spread of less than or equal to 90 degrees and greater than or equal to 15 degrees. In certain embodiments, the feature can be a nanoscale, high aspect ratio feature such as narrow, deep trench, a small diameter, deep hole, or a dual damascene structure. Such features are often found in integrated circuit devices.

### CROSS-REFERENCE TO RELATED APPLICATIONS

This application claims priority to U.S. Provisional Patent Application Ser. No. 61/907,109, filed on Nov. 21, 2013, which herein is incorporated by reference.

### BACKGROUND

1. Field of the Disclosure

Embodiments of the present disclosure generally relate to a thin film deposition method and an apparatus for depositing thin films.

2. Description of the Related Art

In the manufacture of microscale and nanoscale devices, thin films are deposited by a variety of means, such as physical vapor deposition (PVD), chemical vapor deposition (CVD), and atomic layer deposition (ALD). In general, standard thin film deposition techniques will have difficulty filling (or conformally coating) features on a target substrate when the features have high aspect ratios—that is, such features as narrow, deep trenches and small diameter, deep holes.

Standard deposition techniques have problems with so called “overhang” that become apparent when faced with high aspect ratio features at the microscale and nanoscale sizes found in, for example, integrated circuit devices. “Overhang” results when the upper surfaces of a feature in the substrate accumulate deposited material at a faster rate than the lower or bottom surfaces of the feature.

Overhang can result from a variety of causes, such as, there may be a localized depletion of reactive components at the lower surfaces that is caused by the relatively slow diffusion rate of reactive components through narrow openings in a CVD process. Overhang may also result from simple geometry effects such as, for example, volatized molecules in a PVD process will be more likely to impact the upper surfaces of a feature before reaching the lower surfaces because the upper surfaces are between the PVD source and the lower surfaces. But whatever the specific causes, severe overhang may result in a failure to completely fill a feature (or in malformed conformal coatings) if the deposited material in the overhang extends from adjacent sidewalls to close the opening or otherwise significantly shield the lower surfaces from the deposition process.

The severity of overhang during deposition may be somewhat mitigated by optimization of process conditions or tool parameters, such as adjusting chemical precursor pressures or improving linearity of the impinging ions being deposited, and, in general, the amount of overhang is a function of deposited film thickness. But it may not always be possible to simply reduce the deposited film thickness and still achieve desired film properties (e.g., insulating properties) or film quality characteristics (e.g., a lack of “pinholes”). Thus, there is a need in the art to deposit material in high aspect ratio features at the microscale and nanoscale without defects caused by overhang.

### SUMMARY

The present disclosure describes a method of forming a film that includes depositing a film on substrate having a feature with a first surface at a first level and a second surface at a second level, which is not the same as the first level, then removing a portion of the deposited film by exposing the substrate to an ion flux from a linear ion source having a tailored ion angular spread of less than or equal to 90 degrees and greater than or equal to 15 degrees. The ion angular spread is measured from a line approximately normal to the substrate.

In certain embodiments, the feature in the substrate can include an opening at the first level and a bottom surface at the second level. The distance between the first and second levels can be greater than or equal to a width of the opening. The feature can be, for example, a trench, a contact hole, a via, a multilevel feature (e.g., dual damascene structure), or any patterned feature on the wafer on which a film may be deposited.

In some embodiments, the ion flux may be scanned or rastered across the substrate. In other embodiments, the entirety (or substantially all) of the substrate may be exposed to the ion flux simultaneously. The ion flux may be or may include argon ions.

The process used to deposit the film on the substrate can be, for example, a physical vapor deposition process, a chemical vapor deposition, process, or an atomic layer deposition process. Combinations of these methods may be used to form the film and/or various techniques such as plasma enhancement or radio frequency (RF) assistance can be incorporated in the deposition process.

A thin film deposition apparatus including a substrate support for supporting a substrate and a linear ion source having an ion angular spread that can be tailored to be less than or equal to 90 degrees and greater than or equal to 15 degrees is also described. The ion source of the apparatus provides a flux of ions towards (or directed towards) the substrate on the substrate support. The flux of ions removes at least a portion of the film deposited on the substrate.

The substrate support can be configured to rotate the substrate. In some embodiments, the flux of ions may be scanned across the substrate such that only a portion of the substrate is exposed to the flux of ions at any one time.

Additional embodiments include a deposition apparatus comprising a vacuum chamber and a substrate support therein. A substrate placed on the substrate support can include a feature having a first surface at a first level and a second surface substantially parallel to the first surface at a second level that is not the same as the first level. This deposition apparatus may further include a deposition system connected to or within the vacuum chamber. The deposition system can be configured to deposit a film on the substrate's first and second surfaces. The deposition system may be, for example, a physical vapor deposition system, a chemical vapor deposition system, and/or atomic layer deposition system. A linear ion source that can have a tailored ion angular spread of less than or equal to 90 degrees and greater than or equal to 15 degrees is included in the deposition apparatus. The linear ion source can be configured to provide a flux of ions towards the substrate on the substrate holder and thereby remove at least a portion of the film deposited on the first surface.

### BRIEF DESCRIPTION OF THE DRAWINGS

A more particular description of the disclosure, briefly summarized above, may be had by reference to example embodiments, some of which are illustrated in the appended drawings. It should be noted, however, that the appended drawings illustrate only typical embodiments and are, therefore, not to be considered limiting of the scope of this disclosure, as other embodiments of the present disclosure may be equally effective. Additionally, the drawings are not intended to be to scale or to represent relative size ratios between depicted elements, components, portions, or parts. Depicted elements may be re-shaped, re-oriented, re-sized, and/or rearranged without necessarily departing from the scope of the presented disclosure.

FIG. 1 (prior art) depicts a feature exhibiting overhang formed in a substrate.

FIG. 2 depicts ions from an ion source impinging on a substrate at different angles and an ion angular spread distribution from a linear ion source.

FIG. 3 (prior art) depicts a high aspect ratio feature in a substrate exhibiting an overhang problem.

FIG. 4 (prior art) depicts a high aspect ratio feature having a malformed coating due to an overhang problem.

FIG. 5 is a flowchart of a method for depositing a thin film.

FIG. 6 depicts a substrate processed according to an embodiment.

FIG. 7 depicts a thin film deposition apparatus.

### DETAILED DESCRIPTION

Rather than simply tuning processing conditions and tool parameters in attempt to mitigate overhang, it is possible to substantially reduce overhang in features formed in a substrate by preferentially removing material deposited on upper surfaces of a high aspect ratio feature as compared to material deposited on lower surfaces of the high aspect ratio feature. Material removal methods may include, for example, ion bombardment processes.

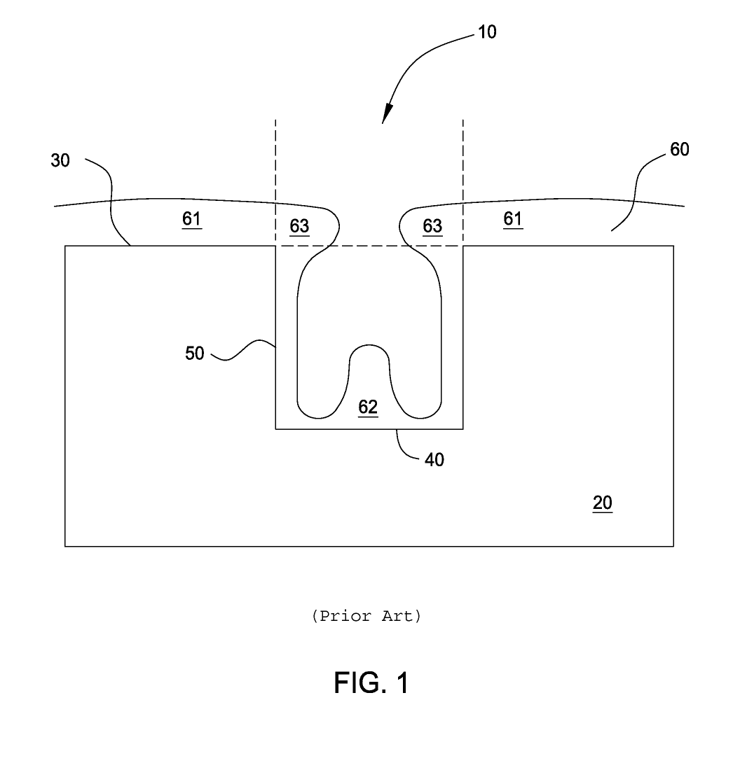

FIG. 1 depicts a feature 10 with a deposited film 60 exhibiting overhang. The feature 10 is formed in or on substrate 20. The feature 10 may be, for example, a trench or a hole etched into substrate 20. Alternatively, the feature 10 may be formed by an additive process by which material is selectively deposited on the substrate 20 to provide the feature 10. Feature 10 has a first surface 30 and a second surface 40. As depicted, the first surface 30 is an upper surface of feature 10 and the second surface 40 is a lower surface of the feature 10.

Here, feature 10 is a nanoscale feature having a high aspect ratio. As used herein, “nanoscale” means less than or equal to 1000 nm (1 micron). “High aspect ratio feature” means that the ratio of the maximum depth of the feature to the minimum width of the feature is greater than or equal to one (1.0). For example, a trench having a width of 500 nm and a depth of 1000 nm would have an aspect ratio of 2.0 and thus, would be a high aspect ratio feature. Similarly, a contact hole having a diameter of 22 nm and a depth of 22 nm would have an aspect ratio of 1.0 and thus would also be an example of a high aspect ratio feature. A feature having a width/diameter of 25 nm and a depth of 100 nm would have an aspect ratio of 4.0 and thus would also be a high aspect ratio feature. A feature having a width/diameter of 22 nm and a depth of approximately 200 nm would have an aspect ratio of approximately 9.1 and thus would also be a high aspect ratio feature.

It should be noted, that many features formed on a substrate may appear more geometrically sophisticated than a feature with a single opening size and depth, but may be considered to be the incorporation of multiple features each with one opening size and depth. For example, a dual damascene feature may be considered to comprise a trench with a via at the trench bottom. Thus, a dual damascene structure having a trench width of 50 nm, a trench length of 200 nm, and depth (to trench bottom) of 100 nm and further including a via in the trench bottom surface that is an ellipse with a minor axis dimension of 50 nm, a major axis dimension of 70 nm, and depth of 60 nm would have an aspect ratio that is 3.2 (that is, (100 nm+60 nm)/50 nm=3.2).

The first surface 30 and second surface 40 of feature 10 are substantially parallel to each other, though either or both surfaces may also include surface roughness, be non-flat, have localized tilt, or faceting such that projections or extensions of these surfaces could result in intersection of the projected/extended surfaces. In this context, “substantially parallel” means the actual (not a projection or conceptual extension) first surface 30 and second surface 40 do not intersect to form a corner.

Feature 10 also has a sidewall 50 that extends between the first surface 30 and the second surface 40. Sidewall 50 is not required to be, though it may be, perpendicular to either the first surface 30 or the second surface 40. In general, overhang may be a greater problem the closer sidewall 50 is to perpendicular. Sidewall 50 may also form an undercut feature wherein an opening formed in the first surface 30 is narrower than second surface 40—that is, sidewall 50 may angle in towards the middle of feature 10.

Feature 10 when viewed from above (and in a direction normal to the first and second surfaces) may appear as a rectangular or other polygonal shape if feature 10 is a trench or trench-like structure. Feature 10 may appear as a square, a circle, or an ellipsis from above when feature 10 is a contact hole or a via. In general, the specific shape of the feature is not important, though the method is particularly useful for depositing films on substrates including high-aspect ratio features. High aspect ratio features have relatively narrow widths as compared to feature depths. Feature 10 may be comprised of various portions and only certain portions may have a high aspect ratio and the various portions need not have the same aspect ratio. In general, problems related to overhang become more noticeable at sub-micron dimensions (i.e., nanoscale dimensions), but these problems may be present at larger feature dimensions as well.

As a film 60 is deposited on substrate 20 with the intention of filling or coating feature 10, a first portion 61 of the film 60 forms on the first (upper) surface 30 and a second (lower) portion 62 of film 60 forms on the second (lower) surface 40. Film 60 may, for example, comprise a metal such as copper, titanium, or tantalum or any other material capable of being deposited on a substrate.

As discussed, a variety of factors related to deposition techniques or specific process parameters can cause the deposition rate of the first portion 61 of the film 60 to be greater than the deposition rate of the second portion 62. Particularly important in this context is the aspect ratio of feature 10.

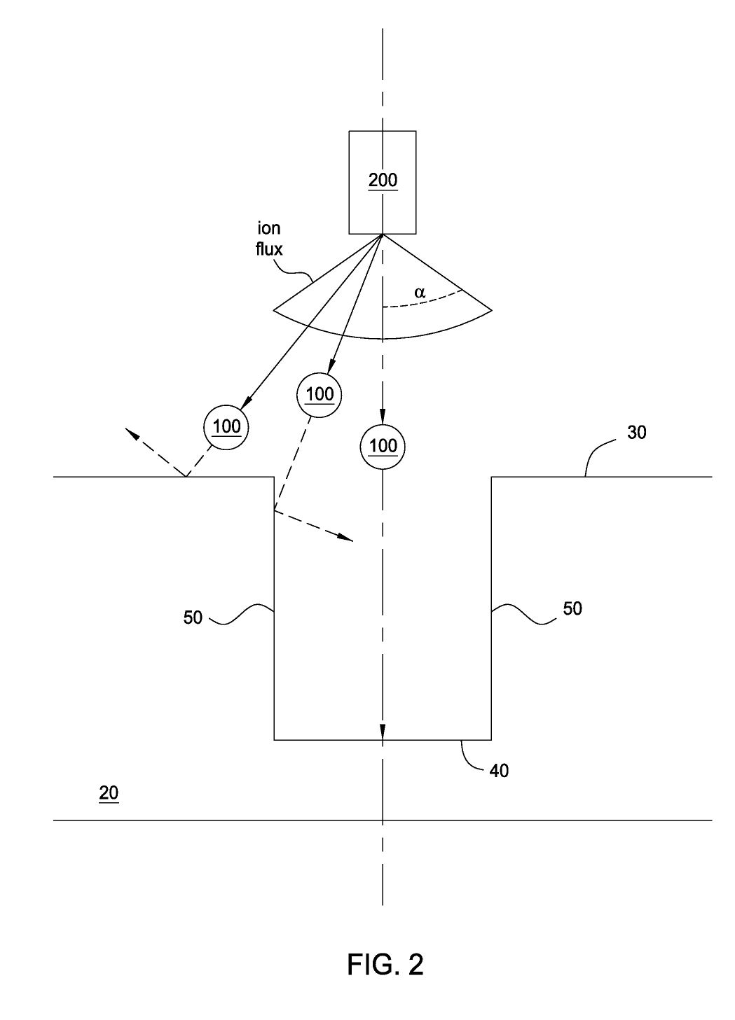

At the nanoscale dimensions often found in semiconductor devices, there will be difficulty getting film precursors (whether reactive compounds or impinging ions or molecules) to the lower portions of a high aspect ratio feature. For example, as depicted in FIG. 2, if impinging ions 100 generated by linear ion source 200 are not travelling perpendicular to the substrate 20, the ions may hit the upper portions of sidewalls 50 before reaching the lower portion of sidewalls 50 or the lower surface 40, and assuming some portion of the impinging ions deposit on the upper sidewalls (or are deflected away from the lower sidewall), there will be fewer ions 100 hitting the bottom surface 40 the lower portions of sidewalls 50.

Overhang may also result because vapor-phase diffusion of reactive precursors into the narrow opening of a high aspect ratio feature is relatively slow such that the concentration of precursors at the upper and lower surfaces may be different during the deposition process. This may result in incomplete feature filling or malformed conformal coatings.

In a reactive deposition process, the concentration of precursors at the upper surface 30 may be (or substantially approach) the bulk concentration of precursors in a deposition chamber, while the concentration at the lower surface 40 may be substantially lower than the bulk concentration due the restricted movement of precursor molecules through the very small opening in the upper surface 30. If the opening in the upper surface 30 is less than the mean free path (λ) of the precursor molecules, a Knudsen-type diffusion process may be operative during deposition which may result in different concentrations (resulting from a generally preferential sorting for smaller molecules through such a narrow opening) for precursor molecules at the lower surface. Furthermore, reactive molecules may be depleted by reactions with the upper materials before they reach the lower surface.

FIG. 2 also depicts the ion angular spread (α) of an ion flux generated by a linear ion source 200. The ion angular spread (α) is measured from a centerline substantially normal to substrate 20. In general, an ion flux with an ion angular spread of α includes ions traveling at all angles between ±α, though the number of ions traveling at each specific angles need not be the same as the other angles. The ion angular spread can have various distribution functions such that, for example, high angle ions (e.g., |α|≧45 degrees) are more or less numerous than low angle ions (|α|<45 degrees). Additionally, the energy of the ions at different angles may be different or have a different distribution of energies. It should be noted that the specific angle of incidence of the ions 100 on the substrate 20 depends on the local topography of the substrate 20.

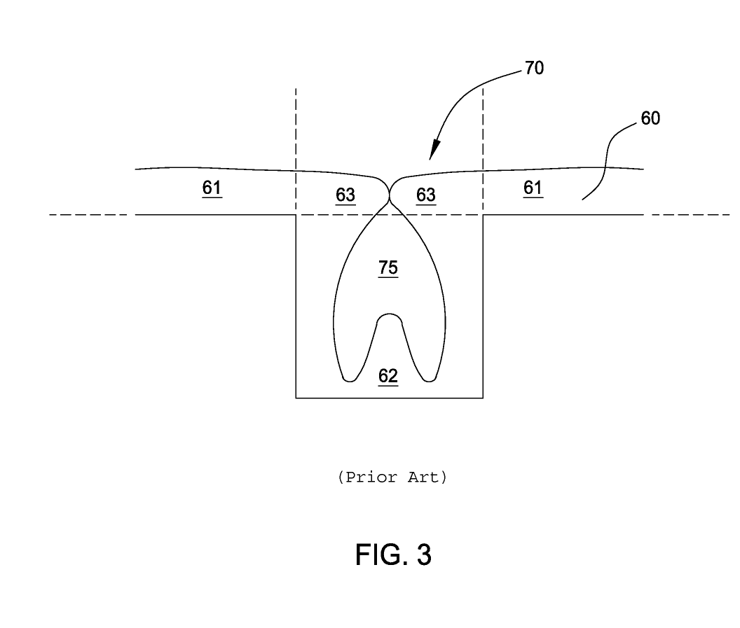

For these and other reasons, film 60 will tend to form an overhang portion 63 as it is deposited on the substrate 20. As the overhang portion 63 extends into the opening between the sidewalls 50, the sidewalls may be further shielded from impinging ions in an RF-assisted process or impinging molecules in a sputter process. Overhang portion 63 may prevent the filling of feature 10 with the deposition material and result in the formation of unintended voids in feature 10 (see FIG. 3).

If a conformal film deposition is desired, overhang portion 63 may cause gaps or thickness variations in the film deposited on the surfaces of feature 10 because, in general, if the surfaces of feature 10 are exposed to different processing conditions (e.g., different molecule incidence rates, different precursor concentrations, etc.), a perfectly conformal film will not form in on these surfaces.

Feature 70, depicted in FIG. 3, has been incompletely filled by film 60 due to the formation of overhang portion 63 that has resulted in the formation of void 75.

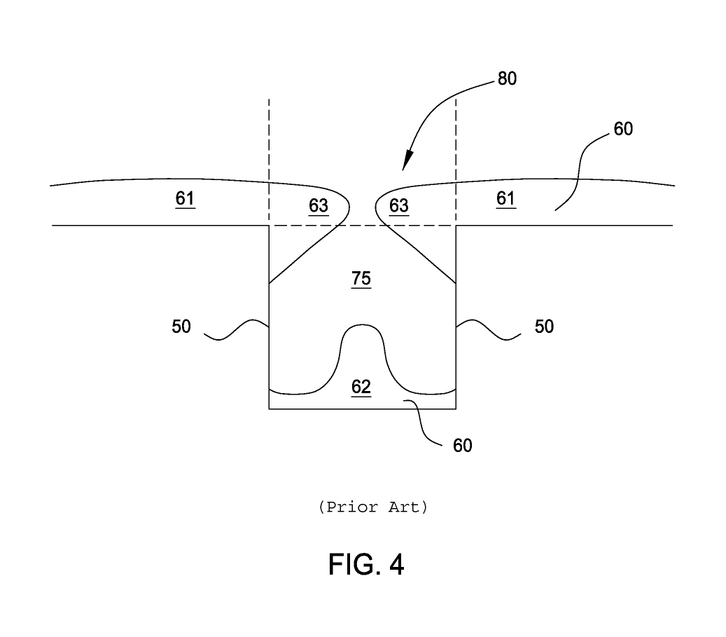

Feature 80, depicted in FIG. 4, has a malformed conformal film 60 caused by the formation of overhang portion 63 preventing incomplete coverage of sidewall 50. Bottom portion 62 is separated from upper portion 61.

In an embodiment of the present disclosure, a method of forming a thin film includes first depositing a thin film on a substrate. After this first deposition, a portion of the deposited film is removed by exposure to an ion flux from a linear ion source having an ion angular spread that can be tailored to be between 90 degrees and 15 degrees. The impinging ions provide a physical etching process which removes portions of the film exposed to the ion bombardment. Due to effects similar to those which produce overhang during a deposition process, the ion flux, which includes ions not incident perpendicularly to the substrate, provides a differential etch rate for material deposited on upper surfaces of feature 10 as compared to material deposited on the lower surfaces of feature 10.

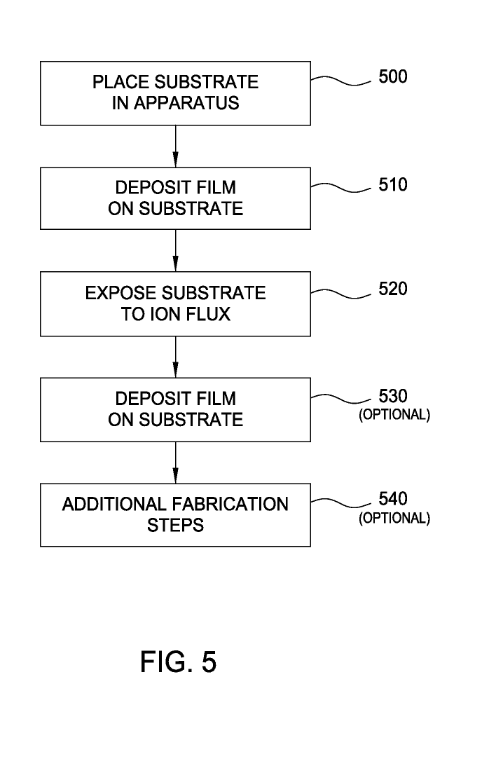

FIG. 5 is a flow chart of the process for forming a thin film on a substrate including a high aspect ratio feature formed therein or thereon. The high aspect ratio feature can be, for example, a trench with a width of approximately 50 nm, a depth of 100 nm, and a length of several microns (1×10⁻⁶ m). In other embodiments, the high aspect ratio feature can be a contact hole with, for example, a diameter of 22 nm and a depth of 50 nm. The substrate may have many different features of various shapes formed therein or thereon including some of which have a high aspect ratio and some of which do not.

In box 500, a substrate 20 is place on a support substrate in a thin film deposition apparatus. The substrate 20 has a feature 10 formed therein. Feature 10 has a first surface 30 and a second surface 40. First surface 30 and second surface 40 are arranged at different levels in substrate 20, but are substantially parallel to each other. As depicted in FIG. 1, first surface 30 is on an upper surface of substrate 20 and second surface 40 is formed towards the interior portion of substrate 20.

In box, a film 60 is deposited on substrate 20. The film 60 can be deposited using, for example, physical vapor deposition methods and in this instance is intended to completely fill feature 10. But as is common in the art, film 60, as initially formed, has an overhang portion 63. An upper portion 61 of film 60 forms on first surface 30 and a lower portion 62 of film 60 forms on second surface 40. Lower portion 62 may also form on all or parts of sidewalls 50.

Film 60 can be, for example, a metal such as copper that is electrically conductive and feature 20 may form part of wiring pattern for an integrated circuit device. In other embodiments, film 60 can be intended to be a conformal coating which is not intended to completely fill feature 20, but would ideally form a coating of approximately constant thickness on surfaces 30 and 40 (and sidewalls 50). A conformal film 60 could be used as, for example, a barrier layer to prevent electromigration from metal layers into dielectric layers.

In box 520, the substrate 20 is exposed to an ion flux supplied by a linear ion source having an angular spread of less than or equal to 90 degrees and greater than or equal to 15 degrees. In box 520, the ions can be, for example, argon ions or other ions of other atoms which are generally chemically inert, or substantially so, under the present processing conditions.

The breadth of the ion angular spread (as may be described by an ion angular distribution function) provides a differential removal rate for film deposited on the upper surfaces (e.g., first surfaces 30) of the substrate and film deposited on the lower surfaces (e.g., second surfaces 40) of the features in the substrate. That is, ions which are not incident to substrate in a perpendicular manner will generally not reach the lower surfaces (e.g., surfaces covered with film portion 62) of a high aspect ratio feature due to geometry effects, while ions that are incident to the substrate 20 in a perpendicular (or nearly so) manner may reach the lower surfaces of the high aspect ratio feature.

As a simple approximation, the removal rate of film 60 can be considered a direct function of the number of ions hitting the film per unit time (which may be referred to as an ion flux). Thus, the removal rate of a material (film portion 62) on the lower surface of the high aspect ratio feature will be less than removal rate of material on the upper surfaces of the substrate because the material at the upper surface (e.g., film portion 61 and overhang portion 63) will be subjected to ions impinging in a perpendicular (or nearly so) manner plus the ions incident on the substrate at other angles and the lower surfaces of the high aspect ratio feature will only be subjected to those ions incident on substrate at a perpendicular (or nearly so) angle and not those at other angles.

As the material on the upper and lower surfaces are substantially the same material, physical etch rates will be different due to the exposure to what is effectively different ion flux rates. The material etch rates may also be angularly dependent—that is ions impinging on the surfaces at different angles may be more or less effective in removing the material. In general, the angular distribution of the ion flux at the upper and lower surfaces will be different in that the percentage of ions hitting the respective surfaces at various angles will be different, but this effect may not be significant when the overall rate of ions hitting the respective surfaces is significantly different. Thus, for example film portion 61 and overhang portion 63 may be removed by the ion bombardment process more quickly than film portion 62. Therefore, while overhang portion 63 may be substantially removed at least some of film portion 62 can remain.

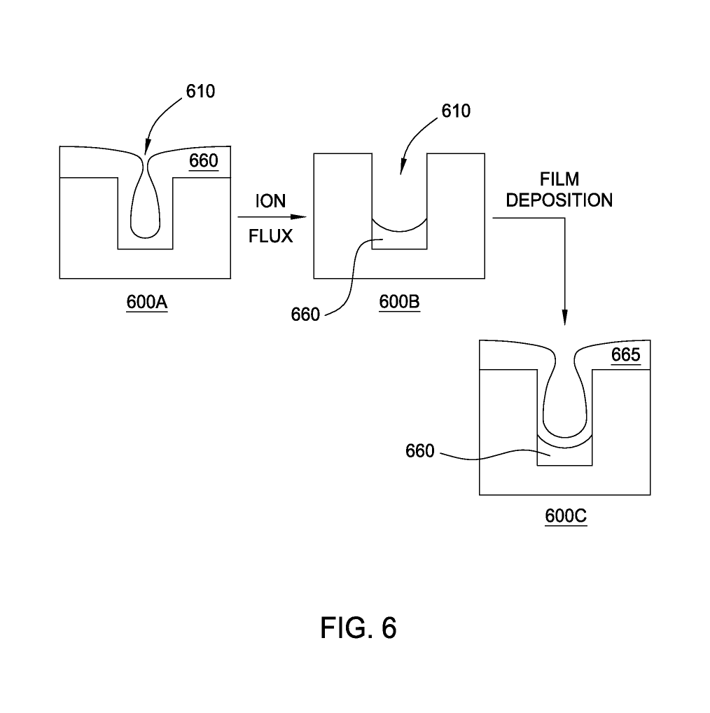

The effect of the process associated with box 520, described above, is depicted in FIG. 6 showing a pre-process substrate 600a and a post-process substrate 600b. Substrate 600a has a feature 610 having with a coating 660 with a substantial overhang into feature 610. Substrate 600b depicts substrate 600a after exposure to an ion flux from a linear ion source with a tailored ion angular spread of less than or equal to 90 degrees and greater than or equal to 15 degrees.

In box 530, an optional second deposition process is performed to generate a filled feature 10. The second deposition process may be the same type process as the first deposition process used to generate initial film 660 or may be a different process type or a variant of the first deposition process. The same or different material as used to form film 660 may be deposited in this process. Box 520 may be repeated after box 530 if desired. FIG. 6 depicts a substrate 600c on which the process of box 530 has been performed. Film 665 has been deposited on substrate 600c over remaining portions of film 660 in process of box 530. As stated, film 665 can be the same or different material used to form film 660. Though not specifically depicted, substrate 600b can undergo various processes such as cleaning, annealing, and/or surface treatments prior to the deposition process of box 530.

In general, the deposition and removal processes may be repeated to fill the feature in stages, but in many applications it may be sufficient to partially fill the feature rather than completely fill the feature. In other applications, the partial removal or paring of the overhang portion may be sufficient to generate a conformal or quasi-conformal coating necessary for subsequent processing. In any event, the deposition (box 530) and removal processes (box 520) may be performed once or any other number of times necessary to achieve the desired result.

Additionally, the removal process in box 520 may be conducted in a single stage or several stages. That is, the ion flux may be continuous or pulsed. Alternatively, in some embodiments only portions of substrate 600a are exposed to an ion flux at any given time because the size (beam diameter) of the ion source is less than the full size of substrate 600a. Thus, portions of substrate 600a may be exposed to multiple passes of the ion flux as the ion flux is scanned and re-scanned across the substrate 600a.

Furthermore, the conditions of the removal process in box 520 need not remain constant and may be varied. Such variations in process conditions may be continuous or in a step-wise manner. For example, in some embodiments, substrate 600a may be rotated during the process of box 520 and the speed of rotation can be varied. In other embodiments, the ion angular spread may be narrowed or widen during the process of box 520, for example, at an initial process phase of box 520, the ion angular spread may be relatively narrow then widened at a later phase of box 520. It is also possible for the process in box 520 to include one or more pauses in ion flux exposure, for example, to control the temperature increase experienced by the substrate.

After the desired film or coating has been achieved, additional processing such as chemical mechanical polishing, electroplating, deposition of interlayer films, photolithographic pattern, or other processing which might be necessary to form a completed device may be conducted in optional box 540.

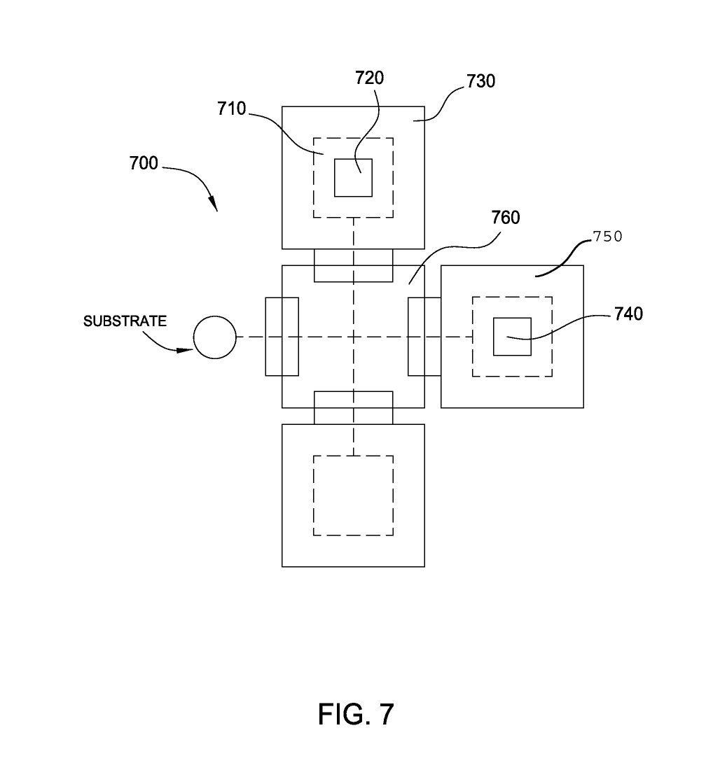

In an embodiment of the present disclosure, deposition and removal may be performed in the same apparatus, though in other embodiments the deposition and removal may be performed in different apparatuses or in a series of different apparatuses such that a first deposition occurs in a first tool, a first removal occurs in a second tool, a second deposition occurs in a third tool, and so forth. The deposition and removal may also be performed in different chambers of the same apparatus, such as a multi-chamber tool depicted in FIG. 7.

FIG. 7 depicts an example apparatus for depositing a film. Chamber 700 may be a vacuum chamber or a controlled-environment chamber that is not necessarily under vacuum. Various pumps, filters, gas feed lines, heating elements, and/or refrigeration elements maybe provided in association with chamber 700, though these elements are not specifically depicted in FIG. 7.

A substrate support 710 is located inside chamber 700. The substrate support 710 is configured to support a substrate such as substrate 600a or substrate 20 during material deposition and removal. Substrate support 710 may be configured to rotate the substrate thereon and/or translate the substrate in horizontal plane. Substrate support 710 may also be capable of translating the substrate in a vertical direction. Substrates can be securely held on substrate support 710 with vacuum suction, electrostatic force, gravity, chemical adhesives, magnetic attraction, clips, clamps, pins, notches, support rings or similar means known in the art. Substrate support 710 may incorporate various components for heating and cooling the substrate.

A linear ion source 720 is provided inside or connected to a sub-chamber 730 such that a flux of ions having an ion angular spread of less than or equal to 90 degrees and greater than or equal to 15 degrees can be provided in a direction towards the substrate. The ion angular spread from the linear ion source 720 can be controlled (tailored) to be less than or equal to 90 degrees and greater than or equal to 15 degrees. The projected shape (that is, the shape of the flux area at the substrate) of the ion flux from linear ion source 720 can be any shape or size. In some embodiments, the ion angular spread is preferably between 90 degrees and 60 degrees (inclusive). In some embodiments, the ions can be supplied with relatively low energy and achieve acceptable etching results.

While chamber 700 can incorporate components for providing an electrical bias to the substrate on substrate support 710, in general, it is preferable that an alternating electrical current bias not be applied to the substrate during the ion flux processing used to remove the portions of deposited films that form overhanging film portions. High biasing may generate plasma sheaths across the substrate and inhibit removal. Large negative bias on the substrate may serve effectively to narrow the ion angle distribution by drawing wide-angle ions toward the substrate. A narrowing of the ion angular spread may be disadvantageous as it is the angular spread which provides the differential removal rates for different portions of the deposited film.

As further depicted in FIG. 7, a deposition system 740 is included in chamber 700. In this embodiment, deposition system 740 is provided in sub-chamber 750. Deposition system 740 may be a physical vapor deposition system including, for example, a metallic target for forming a film on the substrate. The deposition system 740 may include components located outside of chamber 700, though these are not specifically depicted. Deposition system 740 can be a chemical vapor deposition system or an atomic layer deposition system. The deposited film can be a conductive film, a semiconducting film, or an insulating film as required by the process.

Deposition system 740 and linear ion source 720 may be provided in different sub-chambers of chamber 700, as depicted in FIG. 7, or there may no sub-chambers in chamber 700. If sub-chambers are provided, the substrate support 710 may comprise a track or conveyor belt system for transporting the substrate from sub-chamber to sub-chamber. A robotic arm or similar mechanism may be provided for moving substrates between sub-chambers and substrate support 710 may comprise separate wafer chucks in different sub-chambers. Sub-chambers 730 and 750 can be directly connected to each other or there may be an intervening transfer chamber 760 or chambers.

As mentioned, in some embodiments, removal of deposited films may be performed while the substrate is rotated relative to linear ion source. The substrate may be rotated at a constant rate and constant direction or either both the rate and direction can be varied. Alternatively the linear ion source or portions thereof can be rotated relative to the substrate to promote uniformity of ion exposure (dosing). The projected shape of the ion flux can be any shape achievable, e.g., circular, elliptical, polygonal, etc.

In other embodiments, the removal processing may be performed while the substrate is moved (translated) relative to the linear ion source. That is, the substrate may be moved along a conveyor belt mechanism or the like while the ion source remains at a fixed point. In other embodiments, the linear ion source or portions thereof can be translated relative to the substrate. That is, portions of the substrate can be scanned through the ion flux or the ion flux can be rastered across portions of the substrate.

1. A method of forming a film, comprising:
depositing a film on a substrate including a feature with a first surface at a first level and a second surface at a second level that is not the same as the first level; and
removing at least a portion of the film by exposing the substrate to an ion flux from a linear ion source having an ion angular spread of less than or equal to 90 degrees and greater than or equal to 15 degrees.

2. The method of claim 1, wherein the feature includes an opening at the first level and a bottom surface at the second level, and a distance between the first level and the second level is greater than or equal to a width of the opening at the first level.

3. The method of claim 2, wherein the feature is one of a trench, a via, a contact hole, and a dual damascene structure.

4. The method of claim 1, wherein the depositing and the removing are performed repeatedly.

5. The method of claim 1, wherein the ion flux includes argon ions.

6. The method of claim 1, wherein the substrate is rotated during the removing.

7. The method of claim 1, wherein the ion flux is scanned across the substrate during the removing.

8. The method of claim 1, wherein depositing the film comprises at least one of a physical vapor deposition process, a chemical vapor deposition process, and an atomic layer deposition process.

9. The method of claim 1, wherein the ion angular spread is between 90 degrees and 60 degrees.

10. The method of claim 1, wherein the depositing and the removing occur in a single chamber.

11. A thin film deposition apparatus, comprising:
a substrate support configured to support a substrate; and
a linear ion source having a controllable ion angular spread distribution function, the linear ion source configured to provide a flux of ions having an ion angular spread less than or equal to 90 degrees and greater than or equal to 15 degrees towards the substrate on the substrate support and thereby remove at least a portion of a film deposited on the substrate.

12. The thin film deposition apparatus of claim 11, wherein the substrate includes a feature having a first surface at a first level and a second surface substantially parallel to the first surface at a second level that is not the same as first level, and
the feature includes an opening at the first level and a bottom surface at the second level, and a distance between the first level and the second level is greater than or equal to a width of the opening at the first level

13. The thin film deposition apparatus of claim 11, wherein the substrate support is configured to rotate the substrate.

14. The thin film apparatus of claim 11, wherein the flux of ions is scanned across the substrate.

15. The thin film apparatus of claim 11, wherein the film deposited on the substrate is deposited by at least one of a physical vapor deposition process, a chemical vapor deposition process, and an atomic layer deposition process.

16. The thin film apparatus of claim 11, wherein the flux of ions includes argon ions.

17. A deposition apparatus, comprising:
a vacuum chamber;
a substrate support inside the vacuum chamber and configured to support a substrate that includes a feature having a first surface at a first level and a second surface at a second level that is not the same as the first level;
a deposition system in the vacuum chamber and configured to deposit a film on the first surface and the second surface; and
a linear ion source having a controllable ion angular distribution function, the linear ion source configured to provide a flux of ions having an ion angular spread of less than or equal to 90 degrees and greater than or equal to 15 degrees towards the substrate on the substrate holder and thereby remove at least a portion of the film deposited on the first surface.

18. The deposition apparatus of claim 17, wherein the substrate support is configured to rotate.

19. The deposition apparatus of claim 17, wherein the flux of ions includes argon ions.

20. The deposition apparatus of claim 17, wherein the ion angular spread is less than or equal to 90 degrees and greater than or equal to 60 degrees.
